(19) United States
(12) Patent Application Publication
(10) Pub. No.: US 2006/0137859 A1
(43) Pub. Date: Jun. 29, 2006

(54) Heat pipe with high heat dissipating efficiency

(75) Inventor: Kuo-Lung Lin, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/303,575

(22) Filed: Dec. 16, 2005

(30) Foreign Application Priority Data
Dec. 29, 2004 (CN) 200420103587.0

(51) Int. Cl. F28D 15/00; H05K 7/20

(52) U.S. Cl. 165/104.26; 165/104.33; 361/700

(57) ABSTRACT

A heat pipe (20) includes a pipe (22), a plurality of grooves (24), a hydrophilic layer (26), and a liquid operating fluid (28). The pipe includes an evaporator section (30) and an opposite condenser section (32). The grooves are formed on an inside wall (222) of the pipe. The hydrophilic layer is coated on the grooves. The operating fluid is located in the evaporator section. The operating fluid absorbs heat and is vaporized. The vapor is diffused to the condenser section and releases heat, thereby being transformed back into liquid. The liquid is adsorbed by the hydrophilic layer and is reflowed. This adsorption reduces or even avoids a shear force at an interface of the diffusing vapor and the reflowing liquid. Thus, the cyclical speed of the operating fluid is quickened, enhancing the thermal operating efficiency of the heat pipe.

### BACKGROUND

1. Field of the Invention

The invention relates generally to thermal transmitting structures and, more particularly, to a heat pipe with a high heat dissipating efficiency.

2. Discussion of Related Art

Electronic components, such as semiconductor chips, are becoming progressively smaller, while at the same time heat dissipation requirements thereof are increasing. In many contemporary applications, a heat pipe is one of the most efficient systems in use for transmitting heat away from such components.

Referring to FIG. 3 (prior art), a typical heat pipe 10 includes a pipe 102, a capillary structure 104, and a precise amount of liquid operating fluid 106. The pipe 102 is generally made of metal. One end of the heat pipe 102 is an evaporator section 108, and the other end of the heat pipe 102 is a condenser section 110. The evaporator section 108 is disposed in thermal communication with an external heat source, while the condenser section 110 is disposed in thermal communication with an external heat sink. Referring to FIG. 4, the capillary structure 104 is a plurality of grooves and is formed on an inside wall (not labeled) of the pipe 102. Each groove extends along a lengthwise direction (i.e., a direction from the evaporator section 108 to the condenser section 110) of the inside wall of the pipe 102. The operating fluid 106 is sealed in the pipe 102. The operating fluid 106 generally has a high vaporization heat, good fluidity, steady chemical characteristics, and low boiling point, and fluids such as water, ethanol or acetone generally provide these qualities.

An operating principle of the heat pipe 10 is as follows. Liquid operating fluid 106 is originally located in the evaporator section 108 of the heat pipe 10. The external heat source, such as ambient hot air, transmits heat 120 by conduction through the wall of the heat pipe 10 to the liquid operating fluid 106, and the temperature of the liquid operating fluid 106 rises. When the temperature of the liquid operating fluid 106 is equal to a temperature at which the liquid operating fluid 106 changes from the liquid state to a vapor state, the provision of additional heat 120 transforms the liquid operating fluid 106 into a vaporized form thereof Vapor pressure drives the vaporized operating fluid 106 to the condenser section 110 of the heat pipe 10. At the condenser section 110, the vaporized operating fluid transmits the heat 120 absorbed in the evaporator section 108 to the external heat sink (not shown) located at the condenser section 110, and the vaporized operating fluid 106 is thereby transformed back into the liquid operating fluid 106. Capillary action of the grooves 104 and/or gravity moves the liquid operating fluid 106 back to the evaporator section 108. The heat pipe 10 continues this cyclical process of transmitting heat 15 as long as there is a temperature differential between the evaporator section 108 and the condenser section 110, and as long as the heat 120 is sufficient to vaporize the liquid operating fluid 106 at the evaporator section 108.

In use, reflowed liquid operating fluid 106 generally forms liquid drops on the grooves 104, due to gravity and/or capillary action of such grooves 104. This grooving occupies a relatively large inner space in the pipe 102. Thus, a shear force is generally produced at an interface of the diffusing vapors and the reflowing liquid. Not only the shear force can prevent the liquid operating fluid 106 from reflowing to the evaporator section 108, this shear force also can prevent the vaporized operating fluid 106 from diffusing to the condenser section 110. Thus, the cyclical speed of the operating fluid 106 is reduced, thereby reducing the operating efficiency of the heat pipe 10, i.e., the amount of heat dissipated in a given time frame can be expected to decrease.

Furthermore, when the heat pipe 10 is used in a notebook computer, the pipe 102 is generally compressed. The compressed heat pipe has a very small inner space. Therefore, the potential effect due to shear force is much greater. Thus, the cyclical speed of the operating fluid is further reduced, and this further reduces the thermal conductance capabilities of the operating fluid. Thus, the operating efficiency of the compressed heat pipe is very unsatisfactory.

What is needed, therefore, is a heat pipe having high heat dissipating efficiency

### SUMMARY

In one embodiment, a heat pipe includes a pipe, a plurality of grooves, a hydrophilic layer, and an operating fluid. The pipe includes an evaporator section and an opposite condenser section. The grooves are formed on an inside wall of the pipe. The hydrophilic layer is coated on the grooves. The operating fluid is in liquid state and is located in the evaporator section of the pipe. In use, the operating fluid absorbs heat in the evaporator section and is transformed into the vaporized operating fluid. The vaporized operating fluid is diffused to the condenser section and releases heat, thereby being transformed back into liquid operating fluid. The liquid operating fluid is adsorbed by the hydrophilic layer to form a liquid coating and is reflowed to the evaporator section.

Compared with a conventional heat pipe, the present heat pipe adopts the hydrophilic layer. Thus, the reflowed liquid operating fluid is adsorbed by the hydrophilic layer to form the liquid coating. That is, the reflowed liquid operating fluid cannot form liquid drops because the surface tension between the hydrophilic layer and the reformed liquid will not facilitate the creation of liquid drops (i.e., the liquid “wets” the surface of such a layer). Therefore, the reflowed liquid operating fluid occupies relatively small inner space in the pipe. This surface characteristic resultingly reduces or even avoids a shear force at an interface of vapor diffusion and liquid refluence. Thus, the cyclical speed of the operating fluid is quickened, thereby enhancing thermal conductance of the operating fluid, which further improves the operating efficiency of the heat pipe.

Other advantages and novel features of the present heat pipe will become more apparent from the following detailed description of preferred embodiments when taken in conjunction with the accompanying drawings.

### BRIEF DESCRIPTION OF THE DRAWINGS

Many aspects of the present heat pipe can be better understood with reference to the following drawings. The components in the drawings are not necessarily to scale, the emphasis instead being placed upon clearly illustrating the principles of the present heat pipe. Moreover, in the drawings, like reference numerals designate corresponding parts throughout the several views.

FIG. 1 is a cross-sectional view of a heat pipe in accordance with a preferred embodiment of the present device;

FIG. 2 is a cross-sectional view taken along line II-II of FIG. 1;

FIG. 3 is a cross-sectional view of a conventional heat pipe; and

FIG. 4 is a cross-sectional view taken along line IV-IV of FIG. 3.

The exemplifications set out herein illustrate at least one preferred embodiment of the present heat pipe, in one form, and such exemplifications are not to be construed as limiting the scope of the invention in any manner.

### DETAILED DESCRIPTION OF PREFERRED EMBODIMENTS

Reference will now be made to the drawings to describe embodiments of the present heat pipe, in detail.

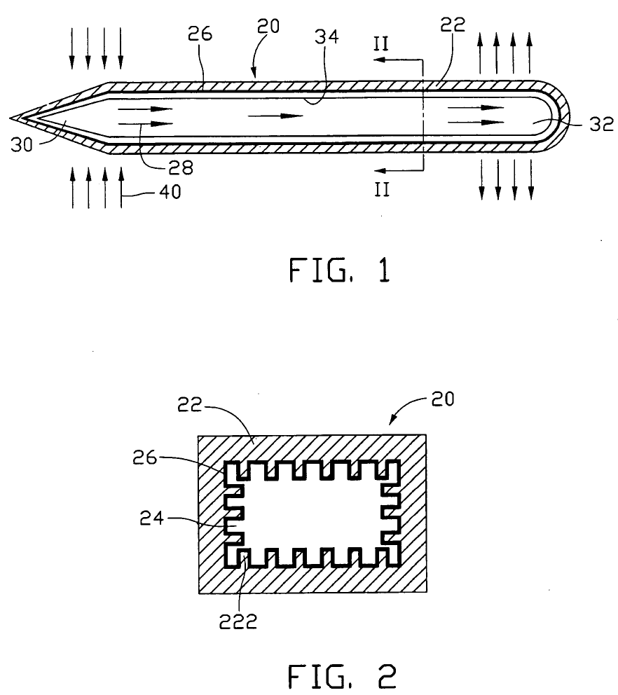

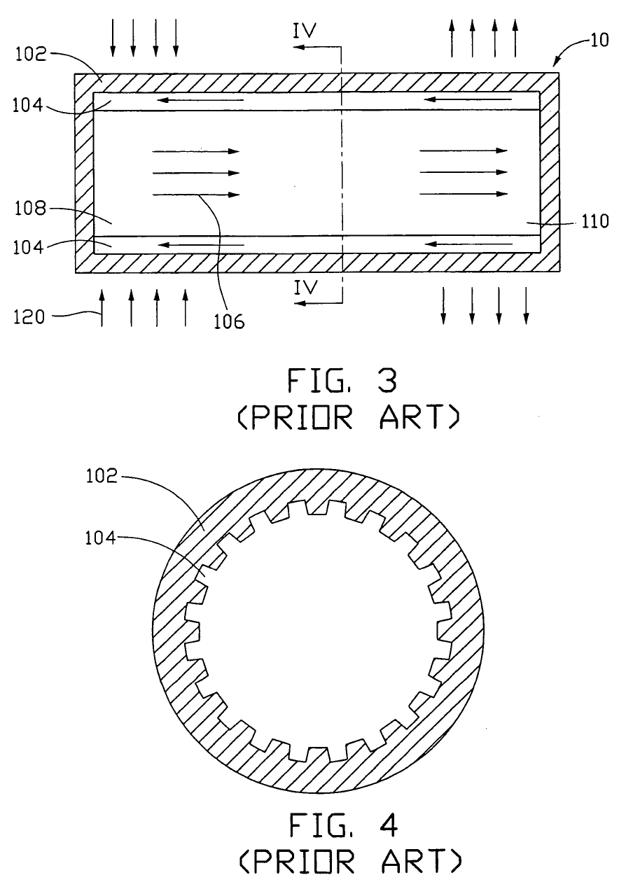

Referring to FIGS. 1 and 2, a heat pipe 20, in accordance with a preferred embodiment of the present device, includes a pipe 22, a capillary structure 24, a hydrophilic layer 26, and a liquid operating fluid 28. The pipe 22 is compressed and closed. The pipe 22 is made of a metal with high thermal conductivity and, advantageously, oxidation resistant, such as copper or aluminum, and so on. A cross-section of the pipe 22 can be circular, elliptical, square, triangular, or rectangular. In the preferred embodiment, the cross-section of the pipe 22 is rectangular. Furthermore, the pipe 22 includes an evaporator section 30 and an opposite condenser section 32. The capillary structure 24 are a plurality of grooves and are formed on an inside wall 222 of the pipe 22. Each groove 24 extends along a lengthwise direction (i.e., a direction from the evaporator section 30 to the condenser section 32) of the inside wall 222 of the pipe 22. The hydrophilic layer 26 is coated on the grooves 24 by means of coating. The hydrophilic layer 26 is advantageously made of organic material with hydrophilicity. In the preferred embodiment, the hydrophilic layer 26 is made of resin. The operating fluid 28 is liquid and is sealed in the pipe 22. The operating fluid 28 has a high vaporization heat (i.e., latent heat of vaporization), good fluidity, steady chemical characteristic, and low boiling point. As such, water, ethanol, or acetone are good candidates for the operating fluid 28.

In use, the evaporator section 30 is disposed in thermal communication with an external heat source (not shown), while the condenser section 32 is disposed in thermal communication with an external heat sink (not shown). The liquid operating fluid 28 is originally located in the evaporator section 30 of the heat pipe 22. The external heat source, such as ambient hot air generated by, e.g., an electronic device or a motor which needs cooling, transmits heat 40 by conduction through the heat pipe 20 to the liquid operating fluid 28, and the temperature of the liquid operating fluid 28 rises. When the temperature of the liquid operating fluid 28 is equal to a vaporization/boiling temperature of the liquid operating fluid 28, the provision of additional heat 40 transforms the liquid operating fluid 28 into a vaporized form thereof. Vapor pressure drives the vaporized operating fluid 28 to the condenser section 32 of the heat pipe 20. At the condenser section 32, the vaporized operating fluid 28 transmits the heat 40 absorbed in the evaporator section 30 to the external heat sink (not particularly shown) located at the condenser section 32, and the vaporized operating fluid 28 is thereby transformed back into the liquid form thereof

Capillary action of the grooves 24 and/or gravity moves the liquid operating fluid 28 back to the evaporator section 30. During this refluence process, the liquid operating fluid 28 is adsorbed by the hydrophilic layer 26 to form a liquid coating 34 and, thus, cannot form as liquid drops thereon. The heat pipe 20 continues this cyclical process of transmitting heat 40 as long as there is a temperature differential between the evaporator section 30 and the condenser section 32, and as long as the heat 40 is sufficient to vaporize the liquid operating fluid 28 at the evaporator section 30.

Compared with a conventional heat pipe, the present heat pipe 20 adopts the hydrophilic layer 26. Thus, the reflowed liquid operating fluid 28 is adsorbed by the hydrophilic layer 26 to form the liquid coating 34. That is, the reflowed liquid operating fluid 28 cannot form liquid drops. Therefore, the reflowed liquid operating fluid occupies a relatively small inner space in the pipe, and a smooth liquid surface represents less of an impediment to gas flow than does a series of liquid drops collected on a surface. This adsorption reduces or even avoids a shear force at an interface of the diffusing vapor and the reflowing liquid. Thus, the cyclical speed of the operating fluid is quickened, and the thermal conductance (i.e., amount of heat transferred in a given time) capability of the operating fluid is improved, which further enhances the operating efficiency of the heat pipe 28.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

We claim:

1. A heat pipe comprising:
a pipe having an inside wall;
a capillary structure formed on the inside wall of the pipe; and
a hydrophilic layer coated on the capillary structure.

2. The heat pipe as claimed in claim 1, wherein the capillary structure is comprised of a plurality of grooves.

3. The heat pipe as claimed in claim 2, wherein each groove extends along a lengthwise direction of the inside wall.

4. The heat pipe as claimed in claim 1, wherein the hydrophilic layer is made of an organic material with hydrophilicity.

5. The heat pipe as claimed in claim 4, wherein the hydrophilic layer is made of a resin.

6. The heat pipe as claimed in claim 1, wherein the pipe is compressed.

7. The heat pipe as claimed in claim 1, wherein the pipe comprises an evaporator section and an opposite condenser section.

8. The heat pipe med in claim 1, wherein the pipe is made of a metal with high thermal conductivity.

9. The heat pipe as claimed in claim 8, wherein the metal is comprised of at least one of copper and aluminum.

10. The heat pipe as claimed in claim 1, further comprising an operating fluid sealed in the pipe.

11. The heat pipe as claimed in claim 10, wherein the operating fluid is a liquid with a high vaporization heat, good fluidity, steady chemical characteristics, and low boiling point.

12. The heat pipe as claimed in claim 11, wherein the liquid is comprised of one of water, ethanol, and acetone.
